(19) United States
(12) Patent Application Publication
(10) Pub. No.: US 2021/0356931 A1
(43) Pub. Date: Nov. 18, 2021

(54) DETERMINING A LASER-ENGRAVED SURFACE USING A REDUCED-ORDER MODEL

(71) Applicant: Standex International Corporation, Salem, NH (US)

(72) Inventors: Francesco IORIO, Toronto (CA); Ian Ross AMELINE, Toronto (CA); Tasso Anastasios KARKANIS, Toronto (CA); Michael Wenhan TAO, Toronto (CA); Massimiliano MORUZZI, Rockford, IL (US); Aaron Michael SZYMANSKI, Toronto (CA)

(21) Appl. No.: 17/317,149

(22) Filed: May 11, 2021

Related U.S. Application Data
(60) Provisional application No. 63/023,778, filed on May 12, 2020.

(51) Int. Cl. G05B 19/18; G06T 17/00

(52) U.S. Cl. CPC G05B 19/182; B23K 26/362; G06T 17/00

(57) ABSTRACT

A computer-implemented method for generating a model of a laser-engraved surface, the method comprising: transforming a first set of values for a first set of parameters associated with a laser-engraving process to a second set of values for a second set of parameters associated with a laser pulse model; modifying the laser pulse model based on the second set of values to produce a modified laser pulse model; and executing the modified laser pulse model to direct a plurality of laser pulses towards a computer-simulated surface, wherein the plurality of laser pulses modify the computer-simulated surface.

### CROSS-REFERENCE TO RELATED APPLICATIONS

This application claims priority benefit of the United States Provisional Patent Application titled, “LASER ENGRAVING SIMULATION WITH ACCOMPANYING STRATEGY GENERATION AND OPTIMIZATION,” filed on May 12, 2020 and having Ser. No. 63/023,778. The subject matter of this related application is hereby incorporated herein by reference.

### BACKGROUND

### Field of the Various Embodiments

The various embodiments relate generally to laser engraving and computer science, and, more specifically, to determining a laser-engraved surface using a reduced-order model.

### Description of the Related Art

Laser engraving is a technique used to obtain a specific geometric pattern on a surface of a material via a focused laser beam. By injecting energy onto the surface using a focused laser beam, discrete locations on the surface are heated, and portions of the material are displaced and/or vaporized. Patterned surface geometries formed in this way can render a desired aesthetic texture on the surface and/or create geometric microstructures that alter the material properties of the material. Laser engraving can be implemented on a wide variety of materials and, therefore, has many useful applications. However, current approaches for developing new laser-engraving processes are very limited.

To obtain a desired surface geometry via laser engraving on a given material surface, many factors need to be accurately determined. Those factors include, without limitation, the number of passes made by a laser over the surface, the specific values of various laser process parameters used to configure the laser for each pass, and the material makeup and initial geometry of the surface. In addition, to balance the trade-off between the quality of a resulting surface geometry and the speed of the laser-engraving process, these factors usually need to be optimized. The process of determining and optimizing these various factors is time-consuming, labor intensive, and prone to error.

Currently, the process of selecting an appropriate laser engraving strategy that accounts for the above factors is manual and based on trial and error. For example, for a targeted surface geometry, a series of laser-engraving experiments is first performed using a laser engraving machine on multiple different surfaces to produce a variety of engraved surfaces. Manual analysis of the resulting engraved surfaces, for example, via an optical or laser surface scanner, can then be used to assess whether any of the laser-engraving experiments produces an engraved surface having surface geometry that adequately approximates the targeted surface geometry. Drawbacks of this type of conventional approach include the time and labor required to perform the laser-engraving experiments and follow-up analysis and the risk that none of the laser-engraving experiments actually produces an engraved surface having surface geometry that adequately approximates the target surface geometry.

In many applications, when modifying a physical process, computer simulations of the physical process are often employed to minimize or even eliminate the need for a trial-and-error experimental approach. With laser-engraving, however, conventional computer simulations have limited utility. In particular, accurately characterizing how a series of laser pulses directed onto a given surface alters the geometry of that surface is a highly complex thermo-mechanical problem. To properly model this type of problem, several factors must be considered, including, and without limitation, the time-transient nature of the energy distribution of a laser pulse, the phase-state change (i.e., melting and/or vaporizing) of the portions of the surface that are treated, the thermal and mechanical effects within the surface associated with heating and cooling, and the secondary effects of the melt pool. To generate accurate results for such a problem using a finite-element method, high-resolution discretization in both space and time is required. Consequently, an accurate simulation of the thermo-mechanical effects of a single laser pulse on a particular surface can take minutes to hours to execute. Extending that approach to the millions or billions of laser pulses employed in generating a single simulated surface associated with a single set of process parameters is entirely impracticable. Performing such a procedure for different combinations of process parameters to determine an optimal laser-engraving solution is even more impracticable.

As the foregoing illustrates, what is needed in the art are more effective ways to implement laser-engraving processes to generate engraved surfaces.

### SUMMARY

A computer-implemented method for generating a model of a laser-engraved surface, the method comprising: transforming a first set of values for a first set of parameters associated with a laser-engraving process to a second set of values for a second set of parameters associated with a laser pulse model; modifying the laser pulse model based on the second set of values to produce a modified laser pulse model; and executing the modified laser pulse model to direct a plurality of laser pulses towards a computer-simulated surface, wherein the plurality of laser pulses modify the computer-simulated surface.

At least one technical advantage of the disclosed techniques relative to the prior art is that the disclosed techniques enable engraved surfaces generated using conventional laser-engraving process parameters to be accurately simulated. Accordingly, with the disclosed techniques, the time and effort required to perform a large number of real-world laser-engraving experiments and analyses to identify a feasible laser-engraving solution can be substantially avoided. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a laser-engraving simulation system configured to implement one or more aspects of the various embodiments.

FIG. 2A schematically illustrates a base function for forming a surface map generated by a laser pulse, according to various embodiments.

FIG. 2B schematically illustrates a surface map after a parameter of a laser model is applied to the base function of FIG. 2A, according to various embodiments.

FIG. 2C schematically illustrates a surface map after another parameter of the laser model is applied to the surface map of FIG. 2B, according to various embodiments.

FIG. 3 sets forth a flowchart of method steps for simulating a laser-engraving process being performed on a surface, according to various embodiments.

FIG. 4 sets forth a flowchart of method steps for training the machine-learning model in the laser-engraving simulation system of FIG. 1, according to various embodiments.

FIG. 5 is a block diagram of a computing device configured to implement one or more aspects of the various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

### System Overview

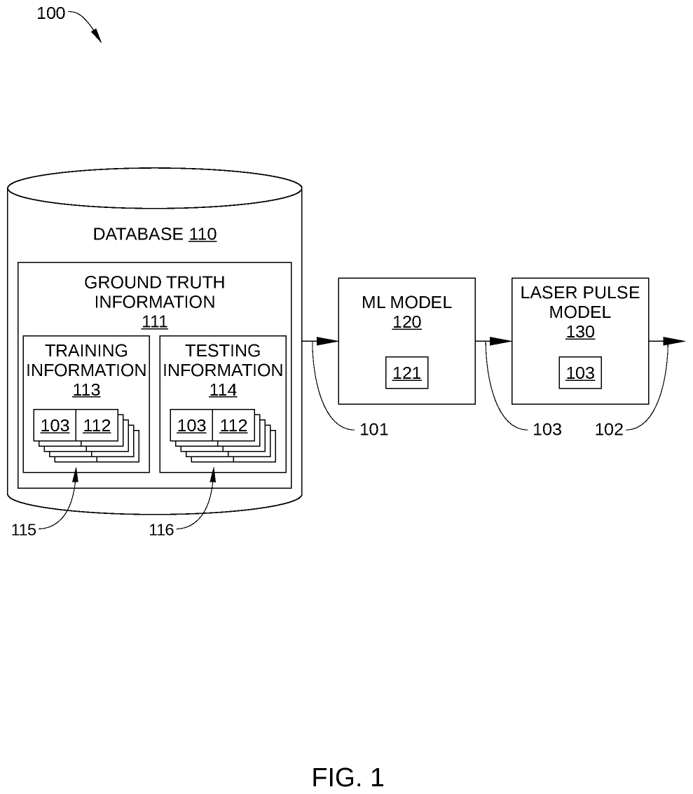

FIG. 1 illustrates a laser-engraving simulation system 100 configured to implement one or more aspects of the various embodiments. Laser-engraving simulation system 100 includes a database 110, a machine learning (ML) model 120, and a laser pulse model 130. Laser-engraving simulation system 100 is configured to generate a simulated laser-engraved surface 102 by simulating a specific laser-engraving process on a workpiece surface (hereinafter a “surface”) having specific material properties and surface geometry. Laser-engraving simulation system 100 generates the simulated laser-engraved surface 102 based on a particular set of values 101 for process parameters of a laser-engraving process, where the set of values 101 defines the specific laser-engraving process. In some embodiments, the process parameters of the laser-engraving process include parameters for the laser source, parameters for the movement of the laser beam with respect to the surface, and parameters for the surface being processed. Thus, in such embodiments, laser-engraving simulation system 100 can generate a simulated laser-engraved surface 102 for any combination of different values of parameters for the laser source, values of parameters for the movement of the laser beam, and/or values of parameters for the surface being processed.

Parameters for the laser source may include laser power, pulse frequency, and/or laser spot size, among others. Parameters for the movement of the laser beam with respect to the surface include engraving speed (e.g., the linear speed at which a laser spot moves across the surface being processed), laser incidence angle with respect to the surface being processed, and/or laser trajectory. In some embodiments, laser incidence angle and laser trajectory are functions of the geometry of a particular laser-engraving system and mirror configuration employed to move a laser beam over the surface. Parameters for the surface being processed may include surface material properties (e.g., melting point, reflectivity, heat capacity, and the like) and surface geometry. In some embodiments, the initial surface geometry of the surface being processed is included in the set of values 101, for example as a height map of the surface.

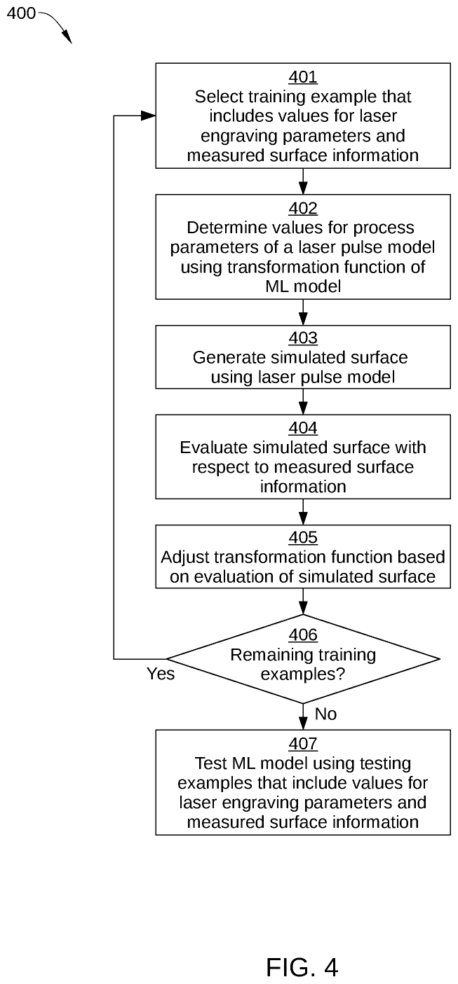

Database 110 stores a plurality of sets of values 101 for the above-described process parameters of a laser-engraving process. For example, in some embodiments, database 110 stores ground truth information 111, which includes a plurality of sets of values 101 for process parameters of the laser-engraving process. In such embodiments, each set of values 101 included in ground truth information 111 is associated with a set of surface measurements 112. Each set of surface measurements 112 includes one or more measurements taken of a physical sample surface that is generated via an associated set of values 101, such as one-dimensional surface profiles and/or two-dimensional maps of the physical sample surface. Thus, each set of values 101 and the associated set of surface measurements 112 can be employed in the training and/or testing of ML model 120, as described in detail below in conjunction with FIG. 4. Surface measurements 112 can be generated via any technically feasible approach, such as laser scanning microscopy, contact stylus profilometry, and/or the like.

In the embodiment illustrated in FIG. 1, ground truth information 111 includes training information 113 and testing information 114. Training information 113 includes a plurality of input pairs 115 that each include a set of values 101 and an associated set of surface measurements 112 and are employed in training ML model 120. Further, the set of values 101 are selected for each input pair 115 to appropriately span the parameter space of the process parameters of the laser-engraving process. Because the process parameters of the laser-engraving process are continuous variables, a dense sampling of the parameter space is generally not possible. Thus, in some embodiments, the set of values 101 for each input pair 115 is selected without generating a full permutation of the process parameter space. For example, in some embodiments, the various values included in each set of values 101 in training information 113 are selected based on a Taguchi or other design of experiments method. In addition, in some embodiments, sets of values 101 for at least some input pairs 115 are selected so that, in training information 113, a range of different degrees of overlap (e.g., from 0% to 95%) between individual laser pulse locations on the physical sample surface are represented.

Similar to training information 113, testing information 114 includes a plurality of input pairs 116 that each include a set of values 101 and an associated set of surface measurements 112. Testing information is employed in testing ML model 120. In addition, the set of values 101 are selected for each input pair 116 to appropriately span the parameter space of the process parameters of the laser-engraving process, so that reliability of ML model 120 can be tested for many different regions of the parameter space of the process parameters of the laser-engraving process.

ML model 120 is a machine-learning model trained to generate a transformation function that receives values for the process parameters of the laser-engraving process and generates corresponding values for the parameters of laser pulse model 130. ML model 120 can be implemented as any technically feasible computer algorithm or network of equations that can improve automatically through experience and information from ground truth information 114. For example, in some embodiments, ML model 120 is implemented as a neural network that receives a vector of inputs (e.g., set of values 101) and returns a vector of outputs (e.g., set of values 103).

In some embodiments, the transformation function generated by ML model 120 is implemented as a parameter transformation algorithm 121. ML model 120 is trained to configure parameter transformation algorithm 121 to generate the corresponding values for laser pulse model 130 so that, when laser pulse model 130 receives the corresponding values as input, laser pulse model 130 can be employed to generate a simulated surface that accurately represents an actual surface. Specifically, the simulated surface has a surface geometry that accurately represents an actual surface that has been treated with a laser-engraving process using the received values for the process parameters of the laser-engraving process. Thus, in some embodiments, once properly trained, parameter transformation algorithm 121 receives a vector representing a set of values 101 for the process parameters of a specific laser-engraving process and generates a vector representing a set of values 103 for the parameters of laser pulse model 130. As described below, laser pulse model 130 simulates, on a pulse-by-pulse basis, the specific laser-engraving process.

Laser pulse model 130 is a reduced-order model that simulates the effect of each individual laser pulse (e.g., a focused energy beam of coherent light) directed to a surface during a laser-engraving process. According to various embodiments, rather than performing a high-resolution, finite-element analysis in space and time for each such laser pulse, laser pulse model 130 includes a geometric model of the effect that a particular laser pulse has on the surface. In the embodiments, the effect can be implemented as a modification to a particular location on a virtual representation of the surface, such as a modification to a surface map of the particular location. Further, in the embodiments, the geometric model determines such effects based on the set of values 103 for the parameters of laser pulse model 130, where the set of values 103 are generated by parameter transformation algorithm 121 based on a set of values 101 for the process parameters of a specific laser-engraving process. Thus, laser pulse model 130 operates in a parametric space in which the solution to a parametric geometric problem (e.g., the modification to a surface map) is contained. The parametric space is based on the parameters of laser pulse model 130, and is a reduced-order space compared to that of a finite-element analysis of the surface.

As noted above, laser pulse model 130 includes a geometric model of the effect that a particular laser pulse has on a surface during a laser-engraving process. In the embodiments, the effect can be implemented as a modification to a particular location on a virtual representation of the surface, such as a modification to a surface map of the particular location.

In some embodiments, the modification to the surface map is implemented as a radially symmetric parametric curve that is determined based on some or all of the set of values 103 for the parameters of laser pulse model 130. In such embodiments, the parametric curve includes two-dimensional height information associated with the location, even though the parametric curve itself is a one-dimensional function. Further, in such embodiments, the parametric curve represents a surface displacement map that is associated with a particular location on a virtual representation of the surface and with a particular laser pulse that is directed to that particular location. In such embodiments, the surface displacement map indicates how the geometry of the particular location is modified by the particular laser pulse. Laser pulse model 130 calculates the shape of the surface displacement map based on the set of values 103 for the parameters of laser pulse model 130. Thus, when laser pulse model 130 is executed with an appropriate set of values 103, a resultant surface displacement map has a size, a shape, and other geometric features of a crater that is formed by the complex thermomechanical processes (e.g., vaporization, melting, and material displacement) associated with a particular high-energy laser pulse being directed to the surface.

In some embodiments, after laser pulse model 130 calculates the shape of the surface displacement map for the particular location, laser pulse model 130 combines the surface displacement map with an existing surface map associated with the particular location. In some embodiments, the surface displacement map is combined with the existing surface map by convolving the surface displacement map with the existing surface map to generate a resultant surface map. Alternatively or additionally, in some embodiments, the surface displacement map is applied to the existing surface map by subtraction of values of the surface displacement map from the existing surface map. In other embodiments, the surface displacement map is combined with the existing surface map by any other suitable approach, such as averaging or interpolating between the surface displacement map and the existing surface map. For example, in one such embodiment, a plane is computed representing an average of a surface of a location prior to a laser pulse being applied and the resultant surface map is determined by interpolating between the average plane and the surface displacement map. Additionally or alternatively, in some embodiments, the combination of the surface displacement map with the existing surface map is performed across a reduced portion of the area addressed by the laser pulse model. For example, in one such embodiment, an averaging, convolution, or interpolating procedure is performed for a central, substantially planar portion of the surface displacement map and a corresponding portion of the existing surface map.

It is noted that, in instances in which one or more other laser pulses have partially overlapped a particular location, the calculated displacement map is combined with a previously modified surface map of the particular location. Specifically, in such instances, the existing surface map of the particular location includes portions of one or more other craters formed by the one or more other laser pulses. By contrast, in instances in which no other laser pulses have partially overlapped the particular location, the existing surface map of the particular location represents a region of untreated surface.

In some embodiments, to more accurately reflect melting of a particular location on a virtual representation of the surface by an incident laser pulse, laser pulse model 130 includes a surface-averaging process. In some embodiments, the surface-averaging process is typically performed on the particular location after combining the displacement map with the existing surface map. Thus, in such embodiments, the modification to the surface map that is determined by laser pulse model 130 includes the surface-averaging process and the combining of the displacement map with the existing surface map. In some embodiments, the surface-averaging process smooths the existing surface map by reducing the magnitude of localized features included in the existing surface map, such as protrusions and/or indentations. In some embodiments, the surface-averaging process includes a Gaussian function to perform such smoothing. Alternatively or additionally, any other suitable smoothing or averaging algorithm can be included in the surface-averaging process. Alternatively or additionally, in some embodiments, the surface-averaging process is based at least in part on one or more of the parameters of laser pulse model 130, such as PULSE_MELT_STRENGTH, PULSE_MELT_RADIUS, AVERAGE_POWER, and/or POWER_SCALE (described below).

In some embodiments, to generate a more accurate surface map of a particular location on a virtual representation of the surface by an incident laser pulse, laser pulse model 130 includes a noise-application process. In such embodiments, the noise-application process is typically performed on the particular location after combining the displacement map with the existing surface map. Thus, in such embodiments, the modification to the surface map that is determined by laser pulse model 130 includes generating the resultant surface map (e.g., by combining the displacement map with the existing surface map) and the noise-application process. In some embodiments, the noise-application process adds a certain quantity of geometric noise to the resultant surface map, for example as a noise map. In some embodiments, the geometric noise added to the resultant surface map includes high-frequency noise and low-frequency noise.

In some embodiments, the noise-application process includes any suitable algorithm for adding noise to the resultant surface map. Alternatively or additionally, in some embodiments, the noise-application process is based at least in part on one or more of the parameters of laser pulse model 130, PULSE_HF_NOISE_BOOST, PULSE_LF_NOISE_BOOST, PULSE_NOISE_BOOST_START, PULSE_HF_NOISE_FACTOR, and/or PULSE_LF_NOISE_FACTOR (described below).

Thus, in such embodiments, parametric noise is added to the resultant surface map that is based on one or more parameters of laser pulse model 130 associated with an attribute of the laser pulse and/or one or more parameters of laser pulse model 130 associated with the surface or surface material.

### Parameters of the Laser Pulse Model

As noted previously, a resultant surface map generated by a particular laser pulse is determined by laser pulse model 130, based on the set of values 103 for the parameters. In some embodiments, the parameters of laser pulse model 130 include one or more parameters associated with a power of a particular laser-pulse, one or more parameters associated with a resultant geometric feature of a crater formed on the surface by the particular laser pulse, one or more parameters associated with noise applied to the resultant geometric feature, and the like.

In some embodiments, laser pulse model 130 includes one or more of the following parameters: a parameter that controls how much towards the average of an existing surface map a bottom portion is adjusted of a displacement for a current laser pulse, referred to herein as AVERAGE_POWER; a parameter that multiplies the parameter AVERAGE_POWER, referred to herein as POWER_SCALE; a parameter that is added to the parameter AVERAGE_POWER, referred to herein as POWER_OFFSET; a parameter that indicates a percentage of a pulse radius that is flat, referred to herein as PULSE_FLAT_BOTTOM; a parameter indicating how much high-frequency noise to add to the displacement map, referred to herein as PULSE_HF_NOISE_FACTOR; a parameter indicating how much low-frequency noise to add to the displacement map, referred to herein as PULSE_LF_NOISE_FACTOR; a parameter indicating a power level at which the radius of a pulse starts increasing, referred to herein as PULSE_SIZE_BOOST_START; a parameter indicating an amount of size boost at 100% power, referred to herein as PULSE_SIZE_BOOST; a parameter indicating a power level at which an amplitude of a crater is boosted, referred to herein as PULSE_CRATER_BOOST_START; a parameter indicating a multiplication factor applied to a crater edge at 100% power, referred to herein as PULSE_CRATER_BOOST, a parameter indicating a power level at which noise (high- or low-frequency) amplitude begins to be boosted, referred to herein as PULSE_NOISE_BOOST_START; a parameter indicating a boost factor for low-frequency noise at 100% power, referred to herein as PULSE_LF_NOISE_BOOST; a parameter indicating a boost factor for high-frequency noise at 100% power, referred to herein as PULSE_HF_NOISE_BOOST; a parameter indicating a Gaussian blur radius that is applied during a surface-averaging process to simulate melting that occurs, referred to herein as PULSE_MELT_RADIUS; and/or a parameter that acts as a blending factor for controlling an intensity of the melting that occurs in the surface-averaging process, referred to herein as PULSE_MELT_STRENGTH. The above parameters are provided by way of example. In other embodiments fewer and/or additional parameters may be included in laser pulse model 130. Such additional parameters may be associated with one or more attributes of a laser pulse and/or the surface or surface material.

### Output of Laser Pulse Model

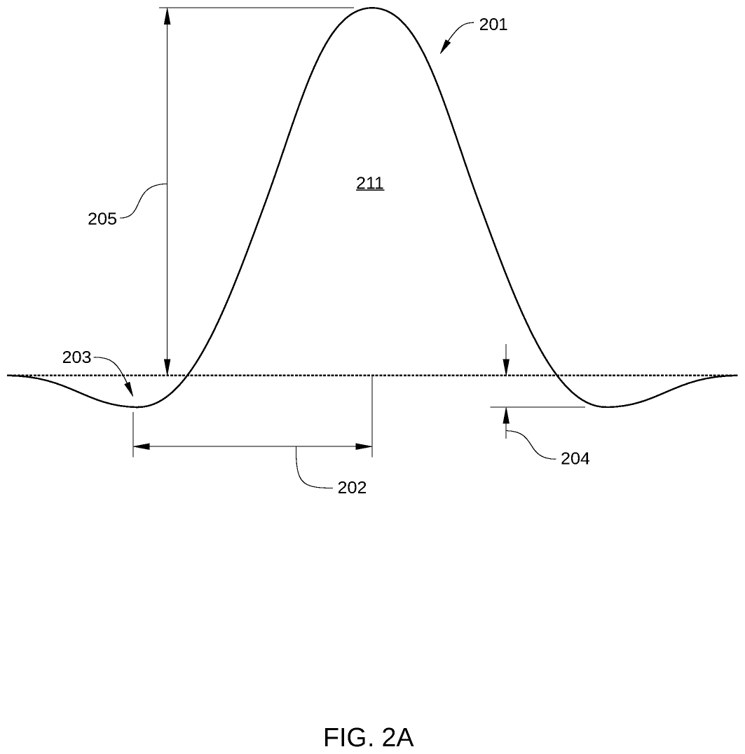

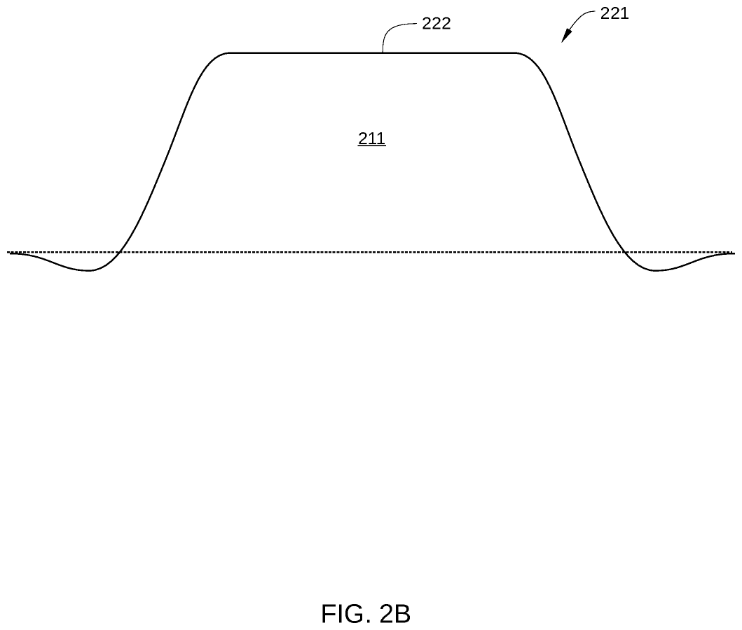

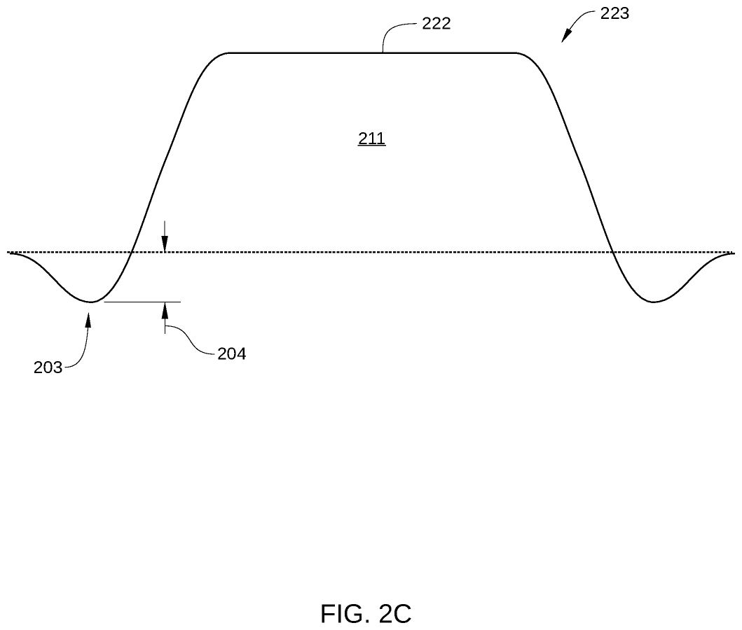

As noted above, to simulate the effect of individual laser pulses directed to a surface during a laser-engraving process, laser pulse model 130 can perform a surface-averaging process, generate a surface displacement map, combine the surface displacement map with an existing surface map to generate a resultant surface map, and/or perform a noise-application process on the resultant surface map. The generation of a surface displacement map is described below in conjunction with FIGS. 2A-2C.

FIG. 2A schematically illustrates a base function 201 for forming a surface map generated by a laser pulse, according to various embodiments. As shown, base function 201 roughly approximates a crater shape (inverted in FIG. 2A), with a crater region 211, a crater radius 202, a burr 203, a burr height 204, and a crater depth 205. In the embodiment illustrated in FIG. 2A, base function 201 is a second order Lanczos function, but in other embodiments, any other suitably shaped function can be employed as base function 201. As noted above, one or more of the parameters of laser pulse model 130 can be applied to base function 201 to change one or more attributes of base function 201 so that base function 201 more closely approximates a shape of a crater formed by a particular laser pulse on a laser-engraved surface. Further, in the embodiment illustrated in FIG. 2A, base function 201 is depicted as a one-dimensional function, but in practice is implemented as a two-dimensional map that is generated based on the radially symmetric one-dimensional function shown.

FIG. 2B schematically illustrates a surface map 221 after a parameter of laser model 130 is applied to base function 201, according to various embodiments. For clarity, surface map 221 is illustrated as a profile curve, but in practice is implemented as a surface map or other two-dimensional function. As shown, providing a non-zero value for a parameter that indicates a percentage of a pulse radius that is flat (e.g., PULSE_FLAT_BOTTOM) causes a bottom portion 222 of surface map 221 to be flat. FIG. 2C schematically illustrates a surface map 223 after another parameter of laser model 130 is applied to surface map 221, according to various embodiments. Similar to surface map 221, surface map 223 is implemented in practice as a surface map or other two-dimensional function. As shown, providing a non-zero value for a parameter indicating a multiplication factor applied to a crater edge (e.g., PULSE_CRATER_BOOST) causes burr height 204 of burr 203 to increase as a consequence of variations in another parameter (e.g., AVERAGE_POWER).

Application of other parameters of laser model 130 to surface maps 221 and/or 223 can further modify the shape of surface maps to more closely approximate a shape of a crater formed by a particular laser pulse. For example, in some embodiments, surface ripples (not shown) formed on bottom portion 222 due to overlapping laser pulses can be averaged out, for example via one or more parameters of laser pulse model 130 associated with the above-described averaging process.

### Determining a Laser-Engraved Surface Using Laser Pulse Model

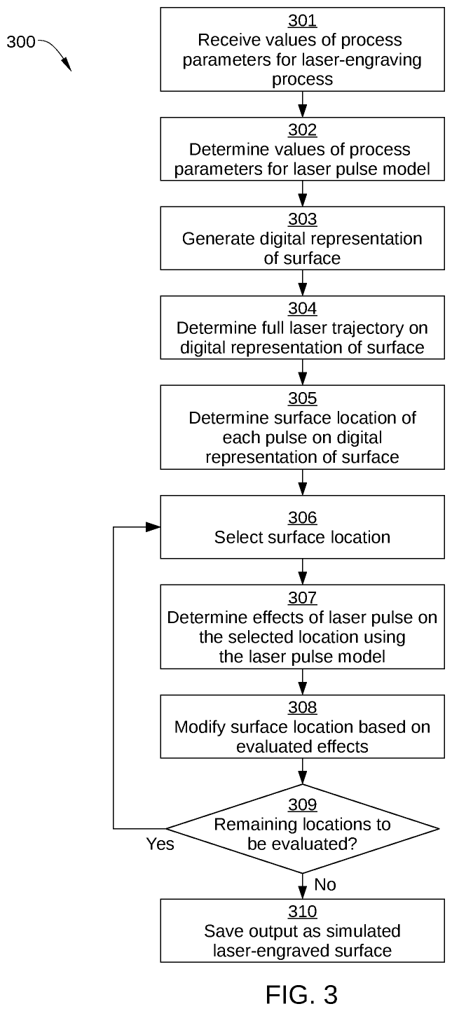

FIG. 3 sets forth a flowchart of method steps for simulating a laser-engraving process being performed on a surface, according to various embodiments. Although the method steps are described in conjunction with the system of FIG. 1, persons skilled in the art will understand that any system configured to perform the method steps, in any order, is within the scope of the embodiments.

As shown, a computer-implemented method 300 begins at step 301, where ML model 120 receives a set of values 101 for the process parameters for a particular laser-engraving process. Set of values 101 includes values for parameters for the laser source, parameters for the movement of the laser beam with respect to the surface, and/or parameters for the surface being processed.

In step 302, ML model 120 determines set of values 103 based on set of values 101.

In step 303, ML model 120 generates a digital representation of the surface being processed. In some embodiments, the digital representation corresponds to a generic surface area of a particular material, and in other embodiments, the digital representation corresponds to a surface on a specific workpiece, such as a specific component to undergo the laser-engraving process.

In step 304, ML model 120 determines a full laser trajectory on the digital representation of the surface. The full laser trajectory indicates the locations on the surface where a laser spot passes during the simulated laser-engraving process. In some embodiments, the full laser trajectory is determined based on the specific mirror configuration of the laser-engraving device to be employed in a corresponding actual laser-engraving process.

In step 305, ML model 120 determines a surface location of each laser pulse on the surface. Generally, ML model 120 determines such locations based on certain values included in the set of values 101, such as laser pulse frequency and engraving speed. In some embodiments, depending on the specific laser-engraving process and the size of the workpiece, the number of such locations can be in the millions or more.

In step 306, ML model 120 selects a single surface location determined in step 305. In step 307, ML model 120 determines the effects of a laser pulse on the selected location, using laser pulse model 130. In step 308, ML model 120 modifies the selected location based on the effects determined in step 307, using laser pulse model 130. In step 309, ML model 120 determines whether there are any remaining surface locations to be evaluated. If yes, method 300 returns to step 306; if no, method 300 proceeds to step 310. In step 310, ML model 120 saves output as a simulated laser-engraved surface 102.

### Training the Machine Learning Model

FIG. 4 sets forth a flowchart of method steps for training machine-learning model 120, according to various embodiments. Although the method steps are described in conjunction with the system of FIG. 1, persons skilled in the art will understand that any system configured to perform the method steps, in any order, is within the scope of the embodiments.

As shown, a computer-implemented method 400 begins at step 401, where ML model 120 selects a training example that includes a set of values 101 and a corresponding set of surface measurements 112. For example, in some embodiments, the training example is an input pair 115 from training information 113 stored in database 110.

In step 402, ML model 120 determines a set of values 103 for the parameters of laser pulse model 130, using the transformation function included in ML model 120 (e.g., parameter transformation algorithm 121). In step 402, the set of values 103 is based on the set of values 101 received in step 401. Thus, in some embodiments, the set of values 101 received in step 401 is an input vector to the transformation function and the set of values 103 is an output vector generated by the transformation function.

In step 403, ML model 120 generates a simulated surface using laser pulse model 130. For example, in some embodiments, the simulated surface is generated using method 300 of FIG. 3.

In step 404, ML model 120 evaluates the simulated surface with respect to measured surface information, such as surface measurements 112. In some embodiments, a plurality of attributes or features of the simulated surface are compared to corresponding attributes or features of the measured surface information. Examples of such attributes or features include crater diameter, surface roughness, burr height, crater depth, and/or the like. In some embodiments, ML model 120 evaluates the simulated surface based on averaging a difference between the simulated surface and measured surface information, minimum and maximum differences between the simulated surface and measured surface information, a geometric mean of differences between the simulated surface and measured surface information, and/or roughness characterizations between the simulated surface and measured surface information.

In step 405, ML model 120 adjusts the transformation function based on the evaluation of the simulated surface in step 404. For example, in some embodiments, back-propagation is employed in ML model 120 to determine how weights and biases within the transformation function are adjusted.

In step 406, ML model 120 determines whether there are any remaining training examples to be included in the training process. If yes, method 400 returns to step 401; if no, method 400 proceeds to step 407. Because the transformation function between the process parameters of the laser-engraving process and the parameters of laser pulse model 130 is relatively complex (e.g., with non-linear, complex interactions between multiple input features), training of the transformation function typically involves a large number of training examples. Thus, in some embodiments, the number of training examples associated with a particular training process can include hundreds or thousands of input pairs 115.

In step 407, ML model 120 undergoes testing. In some embodiments, one or more testing examples are selected and run by ML model 120, and the resulting simulated surfaces are evaluated. For example, a plurality of input pairs 116 from testing information 114 stored in database 110 are selected, run, and evaluated using steps 402, 403, and 404 of method 400. The performance evaluated in step 407 may indicate that further training of ML model 120 is required.

### Exemplary Computing Device

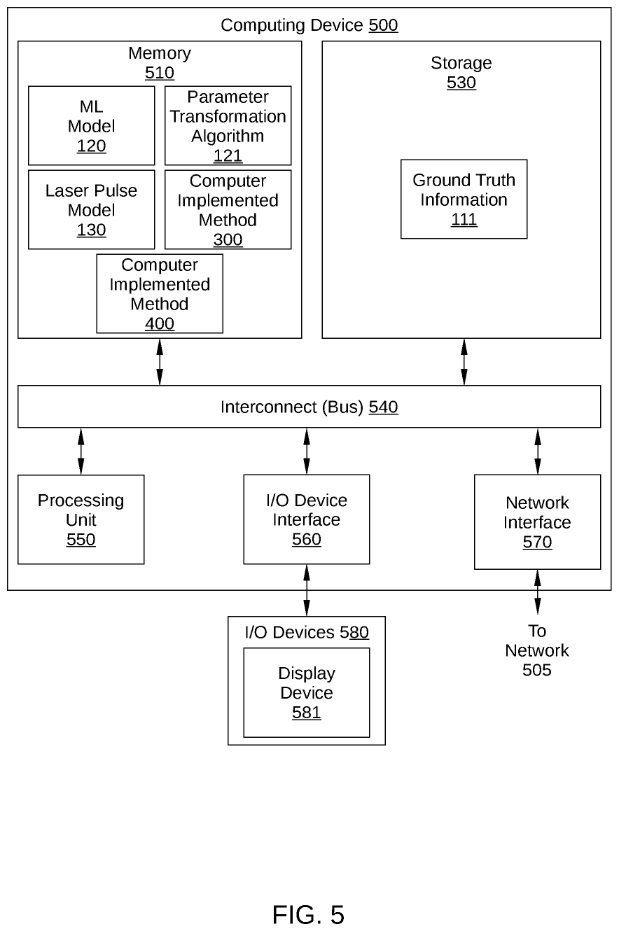

FIG. 5 is a block diagram of a computing device 500 configured to implement one or more aspects of the various embodiments. Thus, computing device 500 can be a computing device associated with laser-engraving simulation system 100. Computing device 500 may be a desktop computer, a laptop computer, a tablet computer, or any other type of computing device configured to receive input, process data, generate control signals, and display images. Computing device 500 is configured to run ML model 120, parameter transformation algorithm 121, laser pulse model 130, computer-implemented method 300, computer-implemented method 400, and/or other suitable software applications, which can reside in a memory 510. It is noted that the computing device described herein is illustrative and that any other technically feasible configurations fall within the scope of the present disclosure.

As shown, computing device 500 includes, without limitation, an interconnect (bus) 540 that connects a processing unit 550, an input/output (I/O) device interface 560 coupled to input/output (I/O) devices 580, memory 510, a storage 530, and a network interface 570. Processing unit 550 may be any suitable processor implemented as a central processing unit (CPU), a graphics processing unit (GPU), an application-specific integrated circuit (ASIC), a field programmable gate array (FPGA), any other type of processing unit, or a combination of different processing units, such as a CPU configured to operate in conjunction with a GPU. In general, processing unit 550 may be any technically feasible hardware unit capable of processing data and/or executing software applications, including ML model 120, parameter transformation algorithm 121, laser pulse model 130, computer-implemented method 300, and/or computer-implemented method 400. Further, in the context of this disclosure, the computing elements shown in computing device 500 may correspond to a physical computing system (e.g., a system in a data center) or may be a virtual computing instance executing within a computing cloud.

I/O devices 580 may include devices capable of providing input, such as a keyboard, a mouse, a touch-sensitive screen, and so forth, as well as devices capable of providing output, such as a display device 581. Additionally, I/O devices 580 may include devices capable of both receiving input and providing output, such as a touchscreen, a universal serial bus (USB) port, and so forth. I/O devices 580 may be configured to receive various types of input from an end-user of computing device 500, and to also provide various types of output to the end-user of computing device 500, such as one or more graphical user interfaces (GUI), displayed digital images, and/or digital videos. In some embodiments, one or more of I/O devices 580 are configured to couple computing device 500 to a network 505.

Memory 510 may include a random access memory (RAM) module, a flash memory unit, or any other type of memory unit or combination thereof. Processing unit 550, I/O device interface 560, and network interface 570 are configured to read data from and write data to memory 510. Memory 510 includes various software programs that can be executed by processor 550 and application data associated with said software programs, including ML model 120, parameter transformation algorithm 121, laser pulse model 130, computer-implemented method 300, and/or computer-implemented method 400.

In sum, the various embodiments described herein provide techniques for the determination of a laser-engraved surface using a reduced-order model. In the embodiments, a set of values for the process parameters of a specific laser-engraving process are transformed to a set of values for the parameters of laser pulse model. The surface geometry of a laser-engraved surface is then determined via a simulation that employs the laser pulse model. Specifically, the effects of each laser pulse of the specific laser-engraving process are determined on a pulse-by-pulse basis.

At least one technical advantage of the disclosed techniques relative to the prior art is that the disclosed techniques enable engraved surfaces generated using conventional laser-engraving process parameters to be accurately simulated. Accordingly, with the disclosed techniques, the time and effort required to perform a large number of real-world laser-engraving experiments and analyses to identify a feasible laser-engraving solution can be substantially avoided. These technical advantages provide one or more technological advancements over prior art approaches.

1. In some embodiments, a computer-implemented method for generating a model of a laser-engraved surface, the method comprising: transforming a first set of values for a first set of parameters associated with a laser-engraving process to a second set of values for a second set of parameters associated with a laser pulse model; modifying the laser pulse model based on the second set of values to produce a modified laser pulse model; and executing the modified laser pulse model to direct a plurality of laser pulses towards a computer-simulated surface, wherein the plurality of laser pulses modify the computer-simulated surface.

2. The computer-implemented method of clause 1, wherein the first set of parameters associated with the laser-engraving process includes at least one of a laser source parameter, a laser movement parameter, or a parameter associated with the computer-simulated surface.

3. The computer-implemented method of clauses 1 or 2, wherein the laser source parameter comprises a power level associated with a laser source employed in the laser-engraving process, a pulse frequency associated with the laser source, or a laser spot size associated with the laser source.

4. The computer-implemented method of any of clauses 1-3, wherein the laser movement parameter comprises an engraving speed of a laser spot across the computer-simulated surface during the laser-engraving process, an incidence angle associated with a laser source employed in the laser-engraving process, or a trajectory associated with the laser.

5. The computer-implemented method of any of clauses 1-4, wherein the parameter associated with the computer-simulated surface comprises a surface material property or a surface geometry.

6. The computer-implemented method of any of clauses 1-5, further comprising generating a virtual representation of the computer-simulated surface based on the first set of values.

7. The computer-implemented method of any of clauses 1-6, further comprising, for each laser pulse included in the plurality of laser pulses, determining a respective location on the virtual representation of the surface based on the first set of values.

8. The computer-implemented method of any of clauses 1-7, wherein, for a laser pulse included in the plurality of laser pulses, determining the respective location on the virtual representation of the computer-simulated surface comprises determining a trajectory of a laser spot across the computer-simulated surface during the laser-engraving process based on at least one value included in the first set of values corresponding to a laser movement parameter associated with a laser source employed in the laser-engraving process.

9. The computer-implemented method of any of clauses 1-8, wherein executing the laser pulse model for the plurality of laser pulses comprises determining, for each laser pulse included in the plurality of pulses, a modification to a virtual representation of the computer-simulated surface at a respective location on the virtual representation of the computer-simulated surface.

10. The computer-implemented method of any of clauses 1-9, wherein determining the modification to the virtual representation of the computer-simulated surface at the respective location comprises modifying a surface map of the virtual representation of the computer-simulated surface at the respective location based on the second set of values.

11. A non-transitory computer readable medium storing instructions that, when executed by a processor, cause the processor to perform the steps of: transforming a first set of values for a first set of parameters associated with a laser-engraving process to a second set of values for a second set of parameters associated with a laser pulse model; modifying the laser pulse model based on the second set of values to produce a modified laser pulse model; and executing the modified laser pulse model to direct a plurality of laser pulses towards a computer-simulated surface, wherein the plurality of laser pulses modify the computer-simulated surface.

12. The non-transitory computer readable medium of clause 11, wherein executing the laser pulse model for the plurality of laser pulses comprises determining, for each laser pulse included in the plurality of pulses, a modification to a virtual representation of the computer-simulated surface at a respective location on the virtual representation of the computer-simulated surface.

13. The non-transitory computer readable medium of clauses 11 or 12, wherein determining the modification to the virtual representation of the computer-simulated surface at the respective location comprises modifying a surface map of the virtual representation of the computer-simulated surface at the respective location based on the second set of values.

14. The non-transitory computer readable medium of any of clauses 11-13, wherein determining the modification to the virtual representation of the computer-simulated surface at the respective location comprises modifying a surface map of the virtual representation of the computer-simulated surface at the respective location via a surface averaging operation that is based on the second set of values.

15. The non-transitory computer readable medium of any of clauses 11-14, wherein determining the modification to the virtual representation of the computer-simulated surface at the respective location comprises: calculating a surface displacement map that is associated with the laser pulse included in the plurality of pulses; and combining the surface displacement map with a surface map at the respective location.

16. The non-transitory computer readable medium of any of clauses 11-15, wherein determining the modification to the virtual representation of the computer-simulated surface at the respective location comprises convolving a surface displacement map with a surface map.

17. The non-transitory computer readable medium of any of clauses 11-16, wherein determining the modification to the virtual representation of the computer-simulated surface at the respective location comprises convolving a first portion of the surface displacement map with a second portion of the surface map that corresponds to the first portion.

18. The non-transitory computer readable medium of any of clauses 11-17, wherein the first portion of the surface displacement map comprises a central, planar region of the displacement map.

19. The non-transitory computer readable medium of any of clauses 11-18, wherein determining the modification to the virtual representation of the computer-simulated surface at the respective location comprises: based on the second set of values, calculating a noise map that is associated with the laser pulse included in the plurality of pulses; and combining the noise map with a surface map at the respective location.

20. A system, comprising: a memory that stores instructions; and a processor that is communicatively coupled to the memory and is configured to, when executing the instructions, perform the steps of: transforming a first set of values for a first set of parameters associated with a laser-engraving process to a second set of values for a second set of parameters associated with a laser pulse model; modifying the laser pulse model based on the second set of values to produce a modified laser pulse model; and executing the modified laser pulse model to direct a plurality of laser pulses towards a computer-simulated surface, wherein the plurality of laser pulses modify the computer-simulated surface.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating a model of a laser-engraved surface, the method comprising:
transforming a first set of values for a first set of parameters associated with a laser-engraving process to a second set of values for a second set of parameters associated with a laser pulse model;
modifying the laser pulse model based on the second set of values to produce a modified laser pulse model; and
executing the modified laser pulse model to direct a plurality of laser pulses towards a computer-simulated surface, wherein the plurality of laser pulses modify the computer-simulated surface.

2. The computer-implemented method of claim 1, wherein the first set of parameters associated with the laser-engraving process includes at least one of a laser source parameter, a laser movement parameter, or a parameter associated with the computer-simulated surface.

3. The computer-implemented method of claim 2, wherein the laser source parameter comprises a power level associated with a laser source employed in the laser-engraving process, a pulse frequency associated with the laser source, or a laser spot size associated with the laser source.

4. The computer-implemented method of claim 2, wherein the laser movement parameter comprises an engraving speed of a laser spot across the computer-simulated surface during the laser-engraving process, an incidence angle associated with a laser source employed in the laser-engraving process, or a trajectory associated with the laser.

5. The computer-implemented method of claim 2, wherein the parameter associated with the computer-simulated surface comprises a surface material property or a surface geometry.

6. The computer-implemented method of claim 1, further comprising generating a virtual representation of the computer-simulated surface based on the first set of values.

7. The computer-implemented method of claim 6, further comprising, for each laser pulse included in the plurality of laser pulses, determining a respective location on the virtual representation of the surface based on the first set of values.

8. The computer-implemented method of claim 7, wherein, for a laser pulse included in the plurality of laser pulses, determining the respective location on the virtual representation of the computer-simulated surface comprises determining a trajectory of a laser spot across the computer-simulated surface during the laser-engraving process based on at least one value included in the first set of values corresponding to a laser movement parameter associated with a laser source employed in the laser-engraving process.

9. The computer-implemented method of claim 1, wherein executing the laser pulse model for the plurality of laser pulses comprises determining, for each laser pulse included in the plurality of pulses, a modification to a virtual representation of the computer-simulated surface at a respective location on the virtual representation of the computer-simulated surface.

10. The computer-implemented method of claim 9, wherein determining the modification to the virtual representation of the computer-simulated surface at the respective location comprises modifying a surface map of the virtual representation of the computer-simulated surface at the respective location based on the second set of values.

11. A non-transitory computer readable medium storing instructions that, when executed by a processor, cause the processor to perform the steps of:
transforming a first set of values for a first set of parameters associated with a laser-engraving process to a second set of values for a second set of parameters associated with a laser pulse model;
modifying the laser pulse model based on the second set of values to produce a modified laser pulse model; and
executing the modified laser pulse model to direct a plurality of laser pulses towards a computer-simulated surface, wherein the plurality of laser pulses modify the computer-simulated surface.

12. The non-transitory computer readable medium of claim 11, wherein executing the laser pulse model for the plurality of laser pulses comprises determining, for each laser pulse included in the plurality of pulses, a modification to a virtual representation of the computer-simulated surface at a respective location on the virtual representation of the computer-simulated surface.

13. The non-transitory computer readable medium of claim 12, wherein determining the modification to the virtual representation of the computer-simulated surface at the respective location comprises modifying a surface map of the virtual representation of the computer-simulated surface at the respective location based on the second set of values.

14. The non-transitory computer readable medium of claim 12, wherein determining the modification to the virtual representation of the computer-simulated surface at the respective location comprises modifying a surface map of the virtual representation of the computer-simulated surface at the respective location via a surface averaging operation that is based on the second set of values.

15. The non-transitory computer readable medium of claim 12, wherein determining the modification to the virtual representation of the computer-simulated surface at the respective location comprises:
calculating a surface displacement map that is associated with the laser pulse included in the plurality of pulses; and
combining the surface displacement map with a surface map at the respective location.

16. The non-transitory computer readable medium of claim 12, wherein determining the modification to the virtual representation of the computer-simulated surface at the respective location comprises convolving a surface displacement map with a surface map.

17. The non-transitory computer readable medium of claim 16, wherein determining the modification to the virtual representation of the computer-simulated surface at the respective location comprises convolving a first portion of the surface displacement map with a second portion of the surface map that corresponds to the first portion.

18. The non-transitory computer readable medium of claim 17, wherein the first portion of the surface displacement map comprises a central, planar region of the displacement map.

19. The non-transitory computer readable medium of claim 12, wherein determining the modification to the virtual representation of the computer-simulated surface at the respective location comprises:
based on the second set of values, calculating a noise map that is associated with the laser pulse included in the plurality of pulses; and
combining the noise map with a surface map at the respective location.

20. A system, comprising:
a memory that stores instructions; and
a processor that is communicatively coupled to the memory and is configured to, when executing the instructions, perform the steps of:
transforming a first set of values for a first set of parameters associated with a laser-engraving process to a second set of values for a second set of parameters associated with a laser pulse model;
modifying the laser pulse model based on the second set of values to produce a modified laser pulse model; and
executing the modified laser pulse model to direct a plurality of laser pulses towards a computer-simulated surface, wherein the plurality of laser pulses modify the computer-simulated surface.
